(19) United States
(12) Patent Application Publication
(10) Pub. No.: US 2015/0014866 A1
(43) Pub. Date: Jan. 15, 2015

(54) Semiconductor Device And Method For Producing A Glass-Like Layer

(71) Applicants: Simon Maus, Berlin (DE); Ulli Hansen, Berlin (DE)

(72) Inventors: Simon Maus, Berlin (DE); Ulli Hansen, Berlin (DE)

(21) Appl. No.: 14/500,054

(22) Filed: Sep. 29, 2014

Related U.S. Application Data
(63) Continuation-in-part of application No. PCT/EP2013/056950, filed on Apr. 2, 2013.

(51) Int. Cl. H01L 23/00; C23C 14/06; H01L 21/02; C23C 14/50; H01L 23/29; H01L 21/56; C23C 14/30; C23C 14/08

(52) U.S. Cl. CPC H01L 23/564; C23C 14/30; C23C 14/0652; C23C 14/081; C23C 14/505; H01L 23/291; H01L 21/56; H01L 21/02178; H01L 21/02167; H01L 21/02269
USPC 257/790; 118/723 EB; 438/127

(57) ABSTRACT

A method for producing a glass-like layer (3) on a substrate, e.g. a power semiconductor substrate (1), is disclosed. The method comprises the deposition of a glass-like layer vapor-deposited material with plasma-assisted electron beam evaporation. An electronic component can be produced using this method.

### CROSS-REFERENCE TO RELATED APPLICATIONS

The present application is a continuation-in-in-part of international patent application number PCT/EP2013/056950 filed by the present inventors on Apr. 2, 2013, which claims the benefit of the filing date of U.S. Provisional Patent Application Ser. No. 61/617,709 filed on Mar. 30, 2012.

The aforementioned provisional patent application is hereby incorporated by reference in its entirety.

### BACKGROUND OF THE INVENTION

1. Field of the Invention

The invention relates to technologies for the manufacture of semiconductor components in power electronics to improve sealing of the semiconductor components. In particular, to meet the demands in reliability of the semiconductor components, for example with respect to moisture-resistance.

2. Brief Description of the Related Art

From the art, methods are known to deposit a glass layer to a substrate. For example, the German patent no. DE 10 2005 044 522 (Schott) teaches a method for the deposition of porous glass layers onto a substrate. The known method comprises the following steps: provision of a substrate and a source of material, followed by deposition of the glass layer with a porosity degree in excess of 1% by Physical Vapor Deposition (PVD) onto the substrate. The method uses a PVD system, which comprises an electron source, a deflecting magnet and an electron source. An electron beam from the electron source is targeted at a disc-shaped target of glass, which is made of low-melding borosilicate glass. The electron beam evaporates the target and the material from the target is deposited on the substrate to form the glass-like layer.

Materials to produce a glass layer are known, e.g., from the international patent application no. WO 03/1008546. This patent application discloses a glass material to produce insulation layers that are used for high-frequency substrates or high-frequency conductive arrangements.

The glass materials described in the prior art have a proportion of alkaline components in the range of up to a few % by weight. These alkaline components may migrate in the strong electrical fields in boundary layers when used in power semiconductor components, thus negatively influencing the circuits of the power semiconductor component.

According to the prior art, high-performance polymers such as polyimides have been preferred to seal surfaces of the power semiconductor components for applications in the field of power electronics. This is disclosed, e.g., in the document US 2008/0224303 A1. These high-performance polymers can be applied and also structured by photolithography processes common in the semiconductor industry. Additionally, these high-performance polymers have a very good dielectric strength.

The curing processes needed after application of the polymer layers in this known method take place at several hundred ° C. This high temperature leads, however, to stress in the polymer layers, due to thermal expansion that differs considerably from the thermal expansion of the substrate made of silicon (a common substrate material for power semiconductors). The differing thermal expansion and related stress may cause a malfunction of the power semiconductor component or increased mechanical stress in the layers below the polymer layer at high temperatures. These high temperatures can occur during operation of the power semiconductor components and may reduce the service life of the power semiconductor component.

Experience has also show that sealing using the high-performance polymers also does not provide sufficient hermeticity against ambient moisture, even if the high-performance polymers are applied with a comparably high layer thicknesses.

### SUMMARY OF THE INVENTION

A method to produce an electrically insulating layer, which hermetically seals against moisture, on a power semiconductor component, using thermal deposition of a glass-like layer of vapor-deposited material, is disclosed. This hermetic encapsulation of the power semiconductor component may be achieved, e.g., by use of at least one thin layer of borosilicate glass and/or in a combination with other glass-like inorganic layers.

The deposition of the glass-like layer may be carried out by plasma-assisted electron beam evaporation in one aspect. The plasma assistance produces a compacting/compaction of the glass-like layer. The compacted glass-like layer has a much lower moisture diffusion and thus can protect a component, and specifically the power semiconductor component, from environmental influences. The properties of the vapor-deposited borosilicate glass layer as a moisture barrier have been demonstrated by temperature and moisture removal performed on silicon substrates. It can be postulated that absorption of moisture into the silicon substrate would cause an increase of the substrate's internal tension and thus result in bending of the coated silicon substrates. Even after storage at 85° C. and 85% rel humidity, no increase of the bending of the silicon substrate could be measured after 1000 hours. Furthermore, the hermeticity of the borosilicate glass layers could be documented by a helium leak test according to Mil Std 883, method 1014. For a layer of approx. 8 μm thickness, a leakage rate of less than 10-⁸ mbar*l/s was measured.

The plasma assistance during the deposition permits targeted influencing of the stresses in the glass-like layer. The vapor-deposited glass-like layers can in this manner and also by varying the composition of their structure be adjusted to match the thermal expansion behavior of the substrate material.

The teachings of this method can be applied for manufacture of the following components in power electronics: PIN-diode, Schottky diode, performance MOSFET, IGBT, BJT or thyristor. For example, the teachings can be used for the production of a sealing layer with an IGBT (insulated gate bipolar transistor), as disclosed in the German patent application no. DE 10 2005 019 178 (Infineon).

### BRIEF DESCRIPTION OF THE DRAWINGS

For a more complete understanding of the present invention and the advantages thereof, reference is now made to the following description and the accompanying drawings, in which:

FIGS. 1-4 show an outline of the deposition of a layer on a substrate.

FIG. 5 shows an apparatus for the production of a sealing layer.

FIG. 6 shows an example of a component with the sealing layer.

### DETAILED DESCRIPTION OF THE PREFERRED EMBODIMENTS

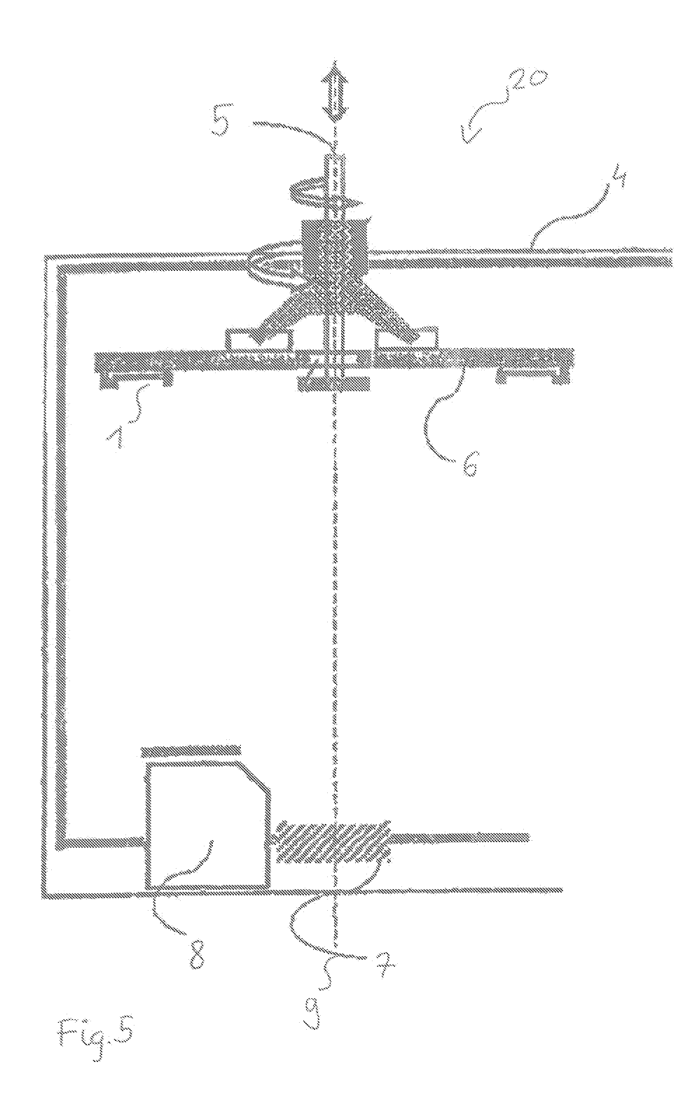

FIG. 5 shows an apparatus 20 for the manufacture of a sealing layer on a semiconductor component. A vacuum chamber 4 has a substrate holder 6, on which substrates and, if applicable, electronic components 1 are placed. The temperature of the substrates (or electronic components 1) to be coated is between 25 and 120° C. during coating. A rotation drive 5 is placed in the vacuum chamber 4 so that the substrate holder 6 can be turned about an axis 9. The vacuum chamber 4 also has an electron beam evaporator 7 and a plasma source 8. The apparatus 20 in FIG. 5 is only illustrated as an example. When used, the vacuum is in the range of 10⁻³ to 10⁻⁶ mbar.

The plasma source 8 is a high-frequency, magnetic-field-assisted plasma source with a matching network, which produces a quasi-neutral plasma jet. For example, noble gas plasmas or oxygen plasmas (or a combination of both) can be used.

An insufficient hermeticity of polymer layers on the substrate or electronic component can be avoided by the direct application of borosilicate layers on a surface of the semiconductor component 1 with the help of apparatus 20. The layers of borosilicate glass have not only a strong barrier effect against ambient moisture but also very good chemical resistance. Additionally, the internal stresses resulting from the plasma-assisted deposition of the layer of borosilicate glass are moderate, as compared to the deposition of the polymer layers. Furthermore, the borosilicate glass has very good electrical properties, e.g., the dielectric strength of the layers is up to 250V/μm.

In the apparatus, layers of borosilicate glass can be produced with a thickness between 50 nm and several tens of μm, and in one aspect between 100 nm and 10 μm. The growth rate is in the range of 100 to 500 nm/min and therefore is higher than in other deposition methods, such as sputtering.

The apparatus 20 permits both direct deposition on the metallization of the semiconductor component 1, and deposition on other inorganic layers, such as silicon nitride. Layers of silicon nitride alone do not have enough of a barrier effect against ambient moisture, and can stress the semiconductor component 1 strongly through the tension applied to the layer bonding, in particular at high layer thicknesses.

In another aspect, the borosilicate glass layer can be deposited onto a glass-like layer of aluminum oxide that had previously been deposited by plasma-assisted electron beam evaporation.

Systems of the borosilicate glass have a very high barrier effect against moisture, as described above. Usually, however, such borosilicate glass systems contain a proportion of alkaline components in the range of up to several % by weight. These alkaline components could migrate into the boundary layer at the substrate in the strong electrical fields found in power semiconductor components, and thus detrimentally influence the circuits in the power semiconductor components. This migration can be avoided by the deposition of especially synthesized alkaline-free glass systems. These alkaline-free glass systems are, however, much more difficult to produce and process than the borosilicate glasses with an alkaline composition. Additionally, adjustment of the expansion behavior can only be implemented to date at the expense of a reduction in the moisture resistance because of the need to vary the composition of the alkaline-free glasses.

Layers of single-component systems, such as aluminum oxide or silicon nitride, form also a kind of diffusion barrier for alkalines, even at low layer thicknesses. These single-component systems can therefore act as barrier layers for the alkaline components. In a layer compound structure having layers from the borosilicate glass, together with such glass-like inorganic layers of single-component systems, the properties of the different layer materials (barrier properties against alkalines on the one hand and barrier properties against ambient moisture on the other hand) can be used beneficially to protect the power semiconductor components 1 from atmospheric influences, such as moisture, whilst still maintaining their function.

Aluminum oxide can be evaporated in a plasma-assisted manner and the deposition can take place in the same apparatus 20. Barrier layers of aluminum oxide can have a thickness between 50 nm and 10 μm, and in one aspect between 100 nm and 4 μm. The barrier layers of silicon nitrides are applied by sputtering or in a CVD process in one aspect of the invention. In addition to the already mentioned inorganic systems, sputtered metallic films of titanium-tungsten or titanium can also be used, as these sputtered films can form a particularly dense nitride phase by the addition of nitrogen gas during the deposition process.

The glass layers described or the combination with the other inorganic glass-like layers can adjust their expansion behavior to the expansion behavior of the substrate 1. This is not possible with the polymer layers known in the art, such as polyimides.

In one variation of the manufacturing method, the deposition of aluminum oxide and borosilicate glass can be carried out in the same apparatus 20 in subsequent process steps. A smooth transfer of the different materials may also be implemented by co-evaporation from different sources. The deposition in the same vacuum chamber 4 means that the substrate 1 (or the layer deposited first) can take up no ambient moisture from the atmosphere between the deposition steps, which could lead to a reduced layer adhesion of the previously deposited layer or additional stresses in the layer composition.

The apparatus 20 permits deposition of the glass-like layer vapor-deposited materials at substrate temperatures below 120° C. This low temperature enables a direct coating of pre-structured resist patterns and therefore gentle additive structuring of the deposited inorganic layers with a beneficial lift-off process.

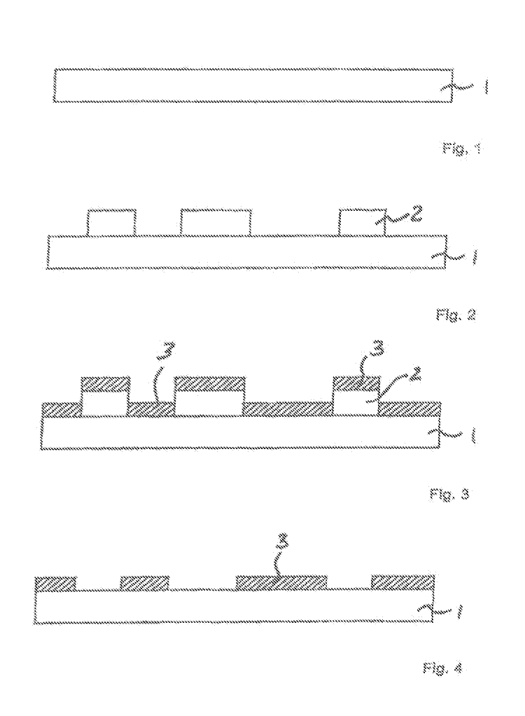

FIGS. 1-4 show an outline of the deposition of a structured layer of vapor-deposited material onto the substrate 1. FIG. 1 shows the substrate 1 to be coated. The substrate 1 can be a semiconductor substrate or a photovoltaic substrate. FIG. 2 shows an illustration of the substrate 1 with a photoresist layer 2 deposited onto the substrate 1. The photoresist layer 2 has microstructures corresponding to a negative pattern of the structured layer to be deposited onto the substrate 1. This photoresist layer 2 is formed by lithography.

In FIG. 3, the substrate 1 is shown with a layer of vapor-deposited material 3 deposited on the substrate 1. This layer 3 of vapor-deposited material can be made up of several layers of different materials as well, depending on the use to which the end product is to be placed. Such different materials can be multi-component systems, such as borosilicate glass or single-component systems such as aluminum oxide.

In one aspect, the multi-component systems of the borosilicate glass have the following composition range:

SiO₂: 65-86%

B₂O₃: 10-30%

Na₂O: 0-5%

Li₂O: 0-5%

K₂O: 0-5%

Al₂O₃: 0-5%

Such systems are disclosed, e.g. in the patent documents (Schott) WO 03/100846 and DE 2005 044 522.

FIG. 4 shows an illustration of substrate 1 from FIG. 3, with the photoresist layer 2 being separated and the deposited layer of the vapor-deposited material being structured on substrate 1.

FIG. 5 shows a schematic of the apparatus 20 for deposition of the layer 3 vapor-deposited material that is applied using a plasma-assisted electron beam vapor-deposit method in this setup.

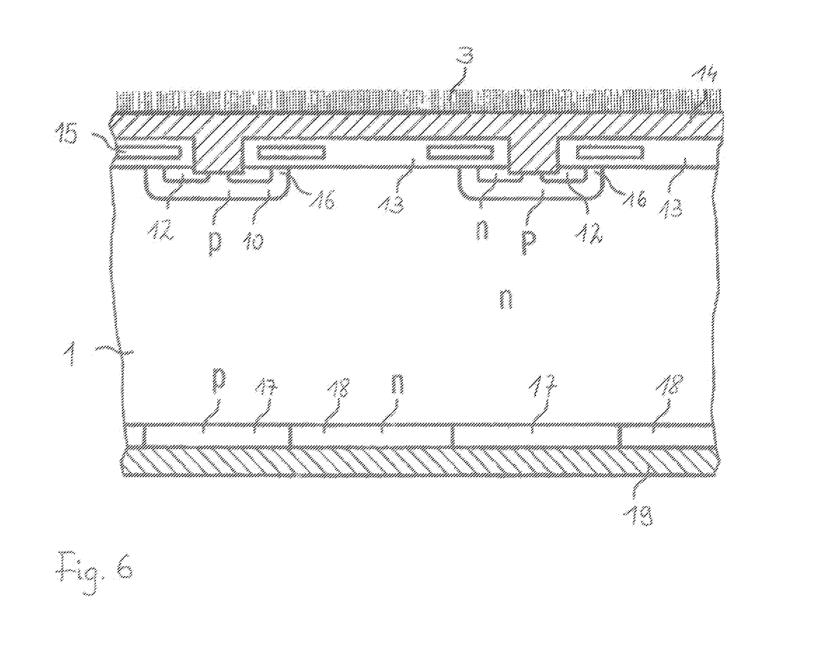

FIG. 6 shows an exemplary electronic component that was produced with the help of the method. FIG. 6 shows an IGBT, as known from patent application no. DE 10 2005 0190 178. However, this method is not limited to such electronic components.

The IGBT has a substrate 1, which is usually made of silicon. On the surface of the substrate 1, there are p-conductive areas 10. The p-conductive area 10 is integrated into an n-conductive zone 11. In each of the p-conductive areas 10, n-conductive areas 12 are provided. The surface of substrate 1 is covered by an electrical insulation layer 13 of, e.g. silicon dioxide. On this electrical insulation layer 13, a metallization layer 14 is formed by known methods. This metallization layer 14 establishes contact between the p-conductive areas 10 and the n-conductive areas 12. In the insulation layer 13, additional electrodes 15, e.g. of polycrystalline silicon, are integrated, which may cause a channel 16 between the n-conductive zones 12 and 11 when voltage is applied.

The front structure is coated by a barrier layer 3 that is produced according to the teachings of this method. This barrier layer 3 serves to protect the entire electronic component from ambient moisture. When using alkaline-containing vapor-depositing materials, this barrier layer 3 may also be formed as a multi-layer system (composite), e.g. of aluminum oxide and a borosilicate glass layer. This barrier layer 3 can also be structured, e.g. to permit contact with the component via metal contacts (not illustrated) at a later time.

On the back of the substrate, p-conductive areas 17 alternate with n-conductive areas 18 that are covered by a rear metallization 19.

### REFERENCE SIGN LIST

1 Substrate or electronic component
2 Photoresist layer
3 Glass-like layer
4 Vacuum chamber
5 Rotation drive
6 Substrate holder
7 Electron beam evaporator
8 Plasma sources
9 Axis
10 p-conductive areas
11 n-conductive zone
12 n-conductive areas
13 Insulation layer
14 Metallization
15 Electrodes
16 Channel
17 p-conductive areas
18 n-conductive areas
19 Rear metallization
20 Evaporation system

What is claimed is:

1. A method for the manufacture of a barrier layer on a substrate, comprising:
deposition of a glass-like vapor-deposited material by means of thermal evaporation of the glass-like layer vapor-deposited material.

2. The method according to claim 1, wherein the thermal evaporation is executed as a plasma-assisted electron beam evaporation.

3. The method according to claim 1, further comprising deposition of further inorganic layers.

4. The method of claim 3, wherein the further inorganic layers comprise at least one of aluminum oxide and/or silicon nitride.

5. The method of claim 1, wherein the barrier layer has a coefficient of thermal expansion substantially similar to a coefficient of thermal expansion of the substrate.

6. The method of claim 1, wherein the substrate comprises a power semiconductor component.

7. An electronic component comprising a substrate as well as a thermally vapor-deposited barrier layer of at least one glass-like layer vapor-deposited material.

8. The electronic component according to claim 7, wherein the thermally-deposited barrier layer comprises further inorganic layers.

9. The electronic component of claim 8, wherein the further inorganic layers comprises at least one layer of aluminum oxide or silicon nitride.

10. The electronic component of claim 9, wherein the barrier layer has a coefficient of thermal expansion substantially similar to a coefficient of thermal expansion of the substrate.

11. An apparatus for the manufacture of a barrier layer from a glass-like layer vapor-deposited material onto a power semiconductor component, and having a substrate holder onto which the substrate can be placed, an electron beam evaporator, and a plasma source.

12. The apparatus according to claim 11, with the substrate holder being rotatable.
